(19) United States
(12) Patent Application Publication
(10) Pub. No.: US 2010/0043851 A1
(43) Pub. Date: Feb. 25, 2010

(54) AUTOMATED SYSTEM FOR CLEANING A PLURALITY OF SOLAR PANELS

(75) Inventors: Mitch Levy, San Jose, CA (US); Emanuel Edward Levy, Saratoga, CA (US)

Correspondence Address: SAWYER LAW GROUP PC, 2465 E. Bayshore Road, Suite No. 406, PALO ALTO, CA, 94303, US

(73) Assignee: MAXIMIZED SOLAR, INC, SAN JOSE, CA (US)

(21) Appl. No.: 12/545,709

(22) Filed: Aug. 21, 2009

Related U.S. Application Data
(63) Continuation of application No. 61/091,122, filed on Aug. 22, 2008.

(51) Int. Cl. B08B 3/00; H01L 31/042

(52) U.S. Cl. 134/56 R; 136/244

(57) ABSTRACT

An automated system for cleaning a plurality of solar energy generation modules is disclosed. The system comprises a control mechanism, at least one tank coupled to the control mechanism, a feeder line coupled to the at least one tank and a spray nozzle arrangement coupled to the feeder line for dispensing a cleaning solution onto the plurality of solar energy generation modules in an automated, predetermined fashion.

### FIELD OF THE INVENTION

The present invention relates solar panel arrangements and more specifically to an automated system for cleaning a plurality of solar energy generation modules.

### BACKGROUND OF THE INVENTION

Home and commercial solar energy generation modules are installed for many reasons. The primary reason, of course, is to reduce the cost of electricity to a home or business. Many people are also trying to do the right thing environmentally by trying to reduce dependence on fossil fuels.

The warranties for solar energy generation modules are for different amounts of time. All solar energy generation modules, however, collect dust and debris over a period of time. If solar energy generation modules are in a dusty area, they are even more impacted with dust and debris. They are also impacted by weather, panel mounting angles, smog, bird droppings and airborne particles.

Dust and debris can reduce solar production from energy generation modules as much as 5% to 25% and more. Solar energy generation modules which have not been cleaned can account for 30% less electrical output over time. Manual cleaning does some good, but on larger sets of energy generation modules this often presents major problems.

Conscientious users clean their energy generation modules approximately every three months. Professional cleaners typically charge between $5 to $10 per panel, so a typical system of 40 energy generation modules would cost $200 or more per cleaning. Additionally, when a building is three or more stories high, this may also result in accessibility problems, which can cause even more expense.

Accordingly, there exists a need for an automated, photovoltaic solar panel cleaning system. The present invention addresses such a need.

### SUMMARY OF THE INVENTION

An automated system for cleaning a plurality of solar energy generation modules is disclosed. The system comprises a control mechanism, at least one tank coupled to the control mechanism, a feeder line coupled to the at least one tank and a spray nozzle arrangement coupled to the feeder line for dispensing a cleaning solution onto the plurality of solar energy generation modules in an automated, predetermined fashion.

Other aspects and advantages of the present invention will become apparent from the following detailed description, taken in conjunction with the accompanying drawings, illustrating by way of example the principles of the invention.

### BRIEF DESCRIPTION OF THE DRAWINGS

FIG. 1 is an overview of a photovoltaic solar panel cleaning system in accordance with an embodiment of the present invention.

FIG. 2 shows a photovoltaic solar panel cleaning system in accordance with a second embodiment of the present invention.

FIG. 3 shows a third embodiment of a photovoltaic solar panel cleaning system in accordance with the present invention.

FIG. 4 illustrates the Inter-Panel bracket and the C bracket in three different representations.

### DETAILED DESCRIPTION

The present invention relates generally to an automated system for cleaning a plurality of solar energy generation modules. The following description is presented to enable one of ordinary skill in the art to make and use the invention and is provided in the context of a patent application and its requirements. Various modifications to the preferred embodiment and the generic principles and features described herein will be readily apparent to those skilled in the art. Thus, the present invention is not intended to be limited to the embodiment shown but is to be accorded the widest scope consistent with the principles and features described herein.

An automated system for cleaning a plurality of solar energy generation modules is disclosed. In the context of the present application what is meant by solar energy generation modules are modules such as solar panels, concentrating mirrors and the like that are utilized for generating electricity. In accordance with varying embodiments, a control mechanism operates in conjunction with a tanking system and a spray nozzle arrangement to periodically disperse a cleaning solution onto a plurality of solar energy generation modules. Consequently, the build up of dust and debris are prevented thereby allowing the solar energy generation modules to generate power at full capacity.

Although the embodiments will be disclosed in the context of cleaning solar panels one of ordinary skill in the art readily recognizes the present invention could be utilized with a variety of solar energy generation modules and that use would be within the spirit and scope of the present invention.

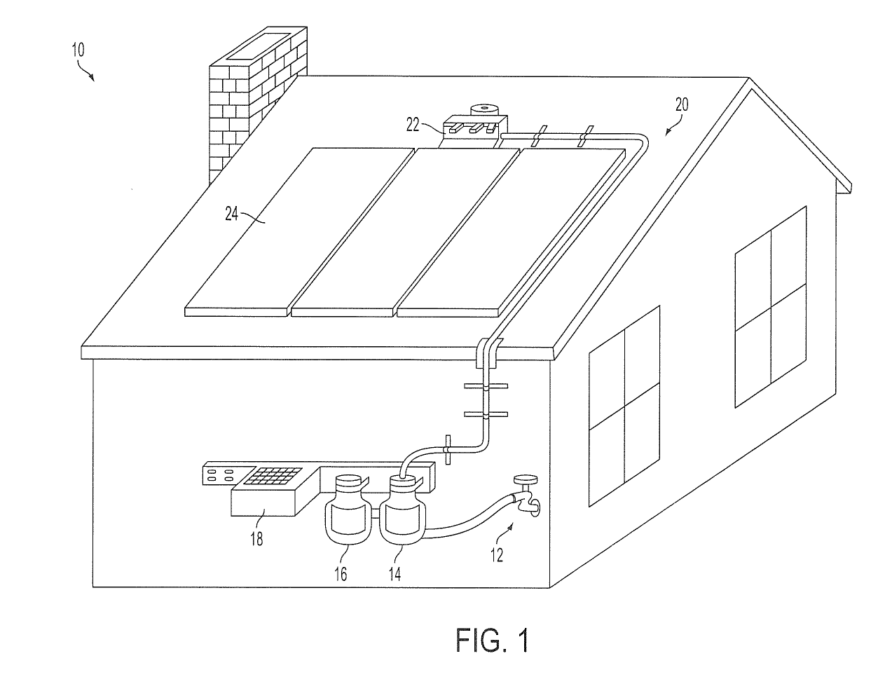

FIG. 1 shows an overview of a system 10 in accordance with an embodiment of the present invention. It should be noted that the cleaning of the photovoltaic solar panels, concentrating mirrors, and windows enhances performance as the dust, debris, snow, and excessive heat that normally accumulates on a panel can reduce efficiency as much as 25% or higher. The system 10 includes a standard hose outlet 12, a main tank 14, a special cleaning solution (surfactant) tank 16, a control mechanism 18, a feeder line 20, a spray nozzle arrangement 22 and a plurality of solar panels 24.

In an embodiment, the control mechanism 18 includes an Application Specific Integrated Chip (ASIC). During operation, the control mechanism 18 initiates a cleaning cycle whereby water from the main tank 14 is mixed with a surfactant from tank 16 and fed to a spray nozzle arrangement 22 via the feeder line 20. The cleaning solution is then dispersed from the spray nozzle arrangement 22 thereby cleaning the plurality of solar panels 24.

One or more of the plurality of panels 24 includes a sensing device on each panel to monitor the panel's performance and relay said performance to the control mechanism 18 or other component. An example of such a sensing device is one that measures various parameters of each individual panel and alerts the control apparatus to any variance. The tanks 14 and 16 can be of any size depending on the desired use. For example, for industrial or commercial buildings, larger tanks can be employed. Additionally, metal treatment such as anodizing will be used where and when appropriate and all materials used will be non-corrosive.

Although the system 10 is described in the context of cleaning the plurality of solar panels 24, one of ordinary skill in the art will readily recognize that the system 10 can be utilized in a variety of fashion while remaining within the spirit and scope of the present invention. For example, the system 10 could be employed to modify the surface of the solar panels, for example Advanced Nano Products company Ltd, manufactures a product that can modify the surface, de-ice the solar panels, cool the solar panels, etc.

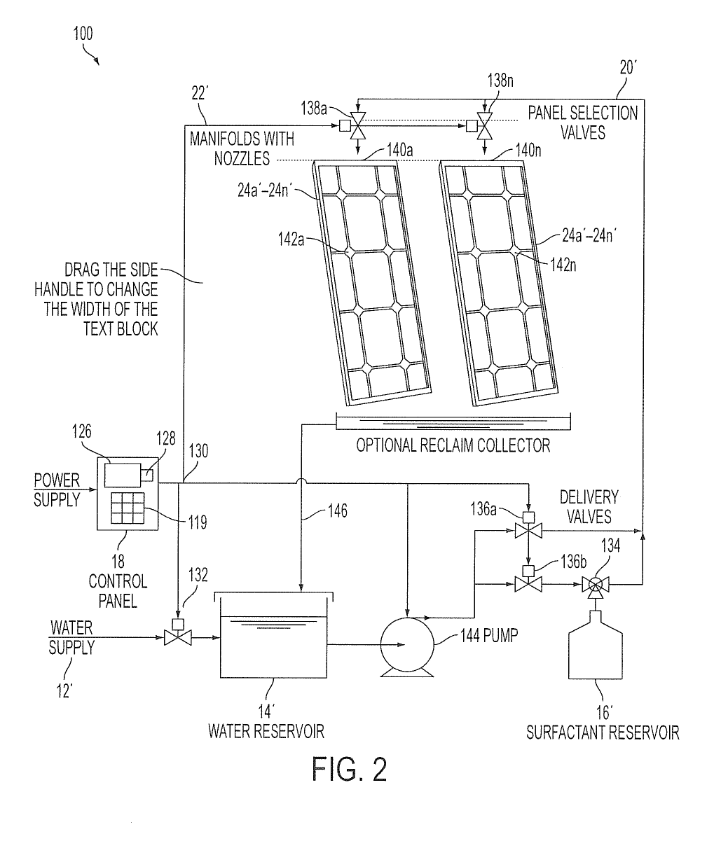

FIG. 2 shows a system 10 in accordance with a second embodiment. Components 12′, 14′, 16′, 18′ 20′, 22′ and 24′ are similar to those described in FIG. 1. The basic unit is a control mechanism 18′ and two reservoirs 14′ and 16′, which attaches to the wall of a building, house, or similar structure, such as that shown in FIG. 1. The control mechanism 18′ includes a small photovoltaic solar panel 119 in the top area of the electronics control system enclosure. This small photovoltaic solar panel 119 and/or an electrical plug charges a battery 126 in the unit which drives a DC motor 128, which rotates a lead screw (not shown) and drives a follower nut 130 to open or close the valve 132 of the main water reservoir 14′.

The secondary reservoir 16′ is controlled by valve 134. The secondary reservoir 16′ feeds the primary reservoir 14′ by gravity (when the valve is open) and allows the “special dirt/debris removing, water repellent, water softening, deicing, surface-modifying, and cleaning solution” (similar or same family as Rain-X) to flow into the main reservoir 14′. When the reservoir 14′ is full, the third valve 136a and 136b is opened by the control mechanism 18′. Line pressure of the garden hose 12′ in connection with the main reservoir 14′ forces the mixture up the feeder tube 20′ to the panel manifold 22′.

The panel manifold 22′ is attached to a central panel or group of panels 24a′-24n′ and has several spray nozzles 140a-140n that allow the mixture to spray out on to the panels 24a′-24n′. Depending on the size of the mounting platform, a minimum of 3 panels can be sprayed at once, with the potential for 7 or more panels to be sprayed at once. Spray time is approximately 45 seconds per cleaning cycle. Dependent on local conditions, approximately once a week the panels will be cleaned by the automated system. However, any of a variety of different schedules could be employed while remaining within the spirit and scope of the present invention.

The manifold 22′ is fed by a water line 20′ from the main reservoir 14′. In certain cases where the panels are on high rooftops, there may be a need for additional pressure. Accordingly, in an additional embodiment, a pump mechanism 144 is employed to provide additional pressure. This can be achieved by compressed CO₂ from a CO₂ capsule or the like. This embodiment is an auxiliary module that is only sold for use with third story or higher roofs or long arrays of photovoltaic panels, concentrating mirrors, and windows. The main reservoir 14′ is connected to the secondary reservoir 16′ by a feeder tube [not shown] that permits a special liquid combination to flow into the reservoir during the mixing cycle.

These functions are controllable by the “onboard” custom-designed ASIC that is powered by the rechargeable storage battery 126 and/or electrical plug. This battery 126 (a lithium ion or comparable type rechargeable battery) is charged daily by a solar cell 119 that is permanently mounted on the controller mechanism 18′. Alternately, a long-lasting non-rechargeable battery may be used where electricity is not readily available.

Also shown is a reclaim collector 148 that collects overflow cleaning solution that falls from the solar panels 140a-140n. Accordingly, a reservoir line 146 feeds the overflow from the reclaim collector 148 to the water reservoir 14′.

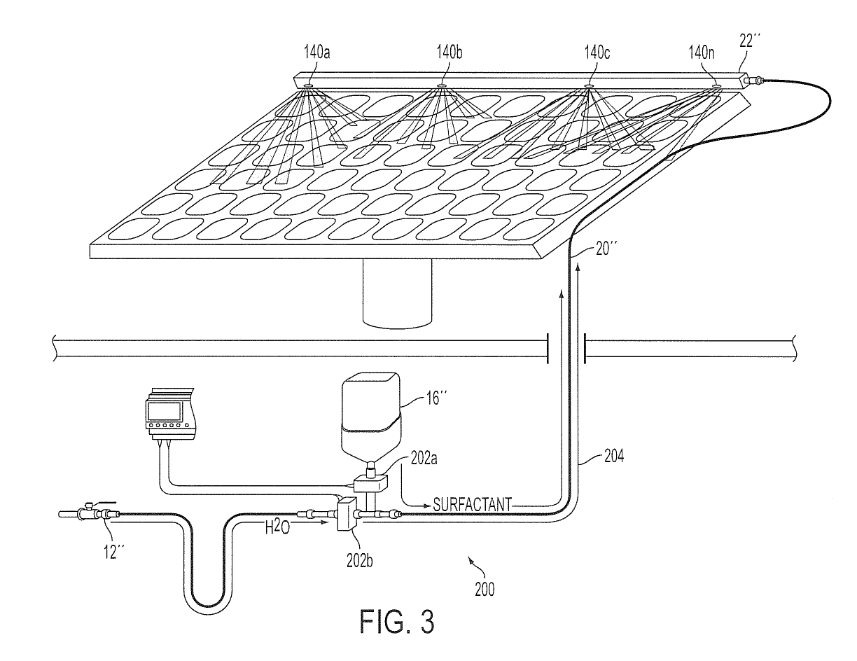

FIG. 3 illustrates a third embodiment 200 of the present invention. In this embodiment, a main storage tank is not included. Here, the control mechanism 18″ is coupled to valves 202a-202b. Valve 202a is coupled to the surfactant reservoir 16″ and valve 202b is coupled to the water line 12″. The surfactant 204 flows with the water 12″ up the feeder tube 20″ to the manifold 22″ with the nozzle array 140a′-140n′.

In all embodiments, the control mechanism 18 is water proof so that in the event of rain there is no leakage. All parts are either high strength, die cast aluminum, injection molded plastic or other “off the shelf” type components. The brackets that hold the feeder lines in place are stampings in aluminum (clear anodized).

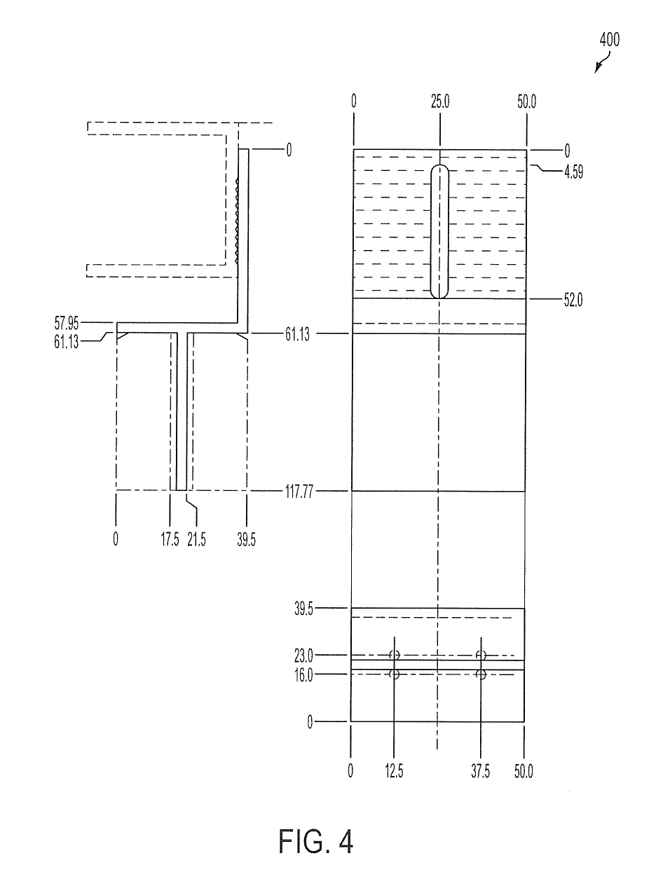

FIG. 4 shows the Inter-Panel Bracket 400 and the “C” Bracket 500 in three different representations. The Inter-Panel Bracket 400 is for closely spaced panels in an array. The bracket drops in between the 2 panels as it is very thin (about ⅛ inch thick). The “C” Bracket 500 is mounted onto the Inter-Panel Bracket 400. The “C” Bracket 500 holds the manifold 22 and it is vertically adjustable. The “C” Bracket allows for the manifold 22 to be adjusted thereby providing “Angular Adjustment” capability to the manifold 22.

An automated system for cleaning a plurality of solar energy generation modules is disclosed. In accordance with varying embodiments, a control mechanism operates in conjunction with a tanking system and a spray nozzle arrangement to periodically disperse a cleaning solution onto a plurality of solar energy generation modules. Consequently, the build up of dust and debris are prevented thereby allowing the solar energy generation modules to generate power at full capacity.

Although the present invention has been described in accordance with the embodiments shown, one of ordinary skill in the art will readily recognize that there could be variations to the embodiments and those variations would be within the spirit and scope of the present invention. Accordingly, many modifications may be made by one of ordinary skill in the art without departing from the spirit and scope of the appended claims.

What is claimed is:

1. An automated system for cleaning a plurality of solar energy generation modules comprising:
a control mechanism;
at least one tank coupled to the control panel;
a feeder line coupled to the at least one tank; and
a spray nozzle arrangement coupled to the feeder line for dispensing a cleaning solution onto the plurality of solar energy generation modules in an automated, predetermined fashion.

2. The system of claim 1 wherein the at least one tank comprises a main tank and a surfactant tank.

3. The system of claim 2 wherein the main tank is coupled to a standard hose outlet.

4. The system of claim 1 wherein the spray nozzle arrangement comprises a manifold and a plurality of nozzles.

5. The system of claim 4 wherein the spray nozzle arrangement further comprises an adjustable bracket coupled to the manifold thereby providing angular adjustment to the manifold.

6. The system of claim 1 wherein the control mechanism comprises:
a motor;
a power source coupled to the motor; and
an integrated circuit coupled to the power source and the motor for controlling the motor wherein the motor opens and closes the at least one tank.

7. The system of claim 6 wherein the power source comprises a battery coupled to a solar cell.

8. The system of claim 2 further comprising a reclaim collector coupled to the main tank.

9. The system of claim 1 wherein the at least one tank is coupled to a valve and the valve is coupled to the control panel and a standard hose outlet whereby the control panel opens and closes the valve.

10. The system of claim 9 wherein the at least one tank contains a surfactant material.

11. The system of claim 1 further comprising a pumping mechanism coupled to the at least one tank.

12. The system of claim 11 wherein the pumping mechanism comprises a CO₂ capsule.

13. The system of claim 1 wherein the plurality of solar energy generation modules further comprise a plurality of solar panels.

14. An automated system a plurality of solar energy generation modules comprising:
a control mechanism;
at least one tank coupled to the control panel;
a feeder line coupled to the at least one tank; and
a spray nozzle arrangement coupled to the feeder line for dispensing a liquid solution onto the plurality of solar energy generation modules in an automated, predetermined fashion.

15. The system of claim 14 wherein the liquid solution is a cleaning solution.

16. The system of claim 15 wherein the cleaning solution is a surfactant.

17. The system of claim 14 wherein the liquid solution is a de-icing solution.

18. The system of claim 14 wherein the liquid solution is a nano surface-modifying solution.

19. The system of claim 14 wherein the control mechanism comprises:
a motor;
a power source coupled to the motor; and
an integrated circuit coupled to the power source and the motor for controlling the motor wherein the motor opens and closes the at least one tank.

20. The system of claim 19 wherein the power source comprises a battery coupled to a solar cell.

21. The system of claim 14 further comprising a pumping mechanism coupled to the at least one tank.

22. The system of claim 21 wherein the pumping mechanism comprises a CO₂ capsule.

23. The system of claim 14 wherein the plurality of solar energy generation modules further comprise a plurality of solar panels.
